(19) United States
(12) Patent Application Publication
(10) Pub. No.: US 2024/0119316 A1
(43) Pub. Date: Apr. 11, 2024

(54) ARRANGEMENT RECOMMENDATION METHOD OF THREE-DIMENSIONAL SPACE AND COMPUTING APPARATUS

(71) Applicant: Yu-Wei Tu, New Taipei City (TW)

(72) Inventors: Yu-Wei Tu, New Taipei City (TW); Chun-Kai Chang, New Taipei City (TW)

(73) Assignee: Yu-Wei Tu, New Taipei City (TW)

(21) Appl. No.: 18/454,817

(22) Filed: Aug. 24, 2023

Related U.S. Application Data
(60) Provisional application No. 63/413,627, filed on Oct. 6, 2022.

(30) Foreign Application Priority Data
Dec. 12, 2022 (TW) 111147642

(51) Int. Cl. G06N 5/04; G06F 30/13; G06Q 30/0601

(52) U.S. Cl. CPC G06N 5/04; G06F 30/13; G06Q 30/0631

(57) ABSTRACT

An arrangement recommendation method of a three-dimensional (3D) space and a computing apparatus are provided. In the method, a 3D space is obtained, and the 3D space is established by scanning a space. Attribute information of the 3D space is identified, and the attribute information includes appearance measurement, space type, furniture type, and/or furniture style. Recommendation information of the 3D space is provided according to the attribute information, and the recommendation information includes a style recommendation and/or a furniture recommendation. Accordingly, the decision-making time for recommendation may be reduced.

### CROSS-REFERENCE TO RELATED APPLICATION

This application claims the priority benefits of the U.S. provisional application Ser. No. 63/413,627, filed on Oct. 6, 2022 and Taiwan application serial no. 111147642, filed on Dec. 12, 2022. The entirety of each of the above-mentioned patent applications is hereby incorporated by reference herein and made a part of this specification.

### BACKGROUND

### Technical Field

The disclosure is related to a knowledge discovery technology, and more particularly, to an arrangement recommendation method of a three-dimensional (3D) space and a computing apparatus.

### Description of Related Art

To simulate a real space, the real space can be scanned to generate a simulated space that appears similar to the real space. The simulated space can be implemented in various applications such as gaming, home decoration, robot navigation, etc. It is worth noting that the interior design and layout of a space typically require recommendations from designers based on their experience.

### SUMMARY

In view of this, the embodiment of the disclosure provides an arrangement recommendation method of a 3D space and a computing apparatus, which may automatically provide suitable arrangement recommendations.

The arrangement recommendation method of the 3D space in the embodiment of the disclosure includes (but not limited to) the following processes. A 3D space is obtained. The 3D space is established by scanning a space. Attribute information of the 3D space is identified, and the attribute information includes appearance measurement, space type, furniture type, and/or furniture style. Recommendation information of the 3D space is provided according to the attribute information. The recommendation information includes a style recommendation and/or a furniture recommendation.

The computing apparatus in the embodiment of the disclosure includes a memory and a processor. The memory is configured to store a code. The processor is coupled to the memory. The processor loads the code to execute to following process. A 3D space is obtained. Attribute information of the 3D space is identified, and recommendation information of the 3D space is provided according to the attribute information. The 3D space is established by scanning a space. The attribute information includes appearance measurement, space type, furniture type, and/or furniture style. The recommendation information includes a style recommendation and/or a furniture recommendation.

Based on the above, according to the arrangement recommendation method of the 3D space and the computing apparatus in the embodiment of the disclosure, once the space is scanned and modeled, the attributes and/or the furniture of the existing space may be analyzed, and appropriate layout recommendations may be generated accordingly. In this way, human errors may be avoided, the time for decision-making may be reduced, and user experience may be enhanced.

In order to make the above-mentioned features and advantages of the disclosure comprehensible, embodiments accompanied with drawings are described in detail below.

### BRIEF DESCRIPTION OF THE DRAWINGS

FIG. 1 is a block diagram of elements of a computing apparatus according to an embodiment of the disclosure.

FIG. 2 is a flowchart of an arrangement recommendation method of a 3D space according to an embodiment of the disclosure.

### DESCRIPTION OF THE EMBODIMENTS

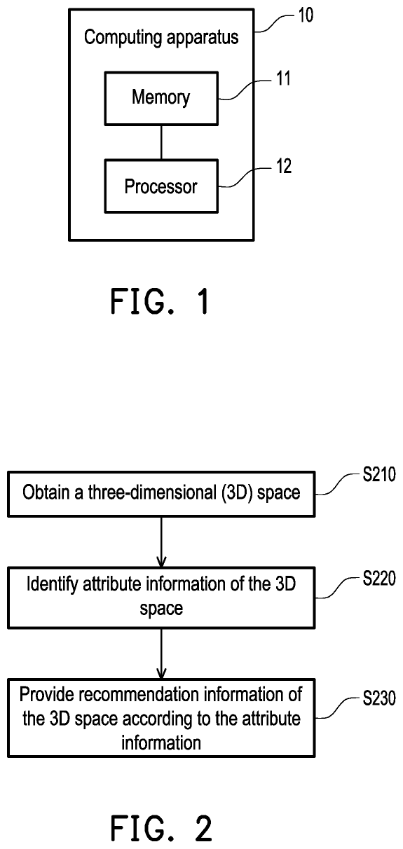

FIG. 1 is a block diagram of elements of a computing apparatus 10 according to an embodiment of the disclosure. Referring to FIG. 1, the computing apparatus 10 may be a mobile phone, a tablet computer, a desktop computer, a laptop, a server, or an intelligent assistant apparatus. The computing apparatus 10 includes (but not limited to) a memory 11 and a processor 12.

The memory 11 may be any type of fixed or movable random access memory (RAM), read only memory (ROM), flash memory, conventional hard disk drive (HDD), solid-state drive (SSD) or similar components. In one embodiment, the memory 11 is configured to store code, software modules, data (e.g., 3D model, attribute information, or recommendation information), or files, which are described in detail in subsequent embodiments.

The processor 12 is coupled to the memory 11. The processor 12 may be a central processing unit (CPU), or other programmable general-purpose or special-purpose microprocessors, a digital signal processor (DSP), a programmable controller, an application-specific integrated circuit (ASIC), other similar components, or combinations of the foregoing. In one embodiment, the processor 12 is configured to execute all or part of the operations of the computing apparatus 10, and may load and execute the code, software module, files, and/or data stored in the memory 11. In one embodiment, the processor 12 performs all or part of the operations of the embodiment of the disclosure. In some embodiments, the software modules or codes stored in the memory 11 may also be implemented by physical circuits.

In the following, the method described in the embodiment of the disclosure is explained with each element in the computing apparatus 10. Each process of the method can be adjusted according to the implementation, and is not limited to thereto.

FIG. 2 is a flowchart of an arrangement recommendation method of a 3D space according to an embodiment of the disclosure. Referring to FIG. 2, the processor 12 obtains the 3D space (step S210). Specifically, the 3D space is created by scanning a space. For example, using image capture apparatus, LiDAR, Time-of-Flight (ToF) detectors, or other sensors to scan the real space and obtain sensing information (e.g., intensity or round-trip time corresponding to different positions), a 3D model (i.e., a 3D space) of this real space may be constructed.

The processor 12 identifies the attribute information of the 3D space (step S220). Specifically, the attribute information includes appearance measurement, space type, furniture type, and/or furniture style. The appearance measurement includes, for example, area, volume, approximate cube size, or total number of spaces of the 3D space. The space type includes, for example, living room, bedroom, dining room, office, toilet, machine operation area, or shopping mall. The furniture type includes, for example, table, chair, cabinet, appliance, or bed. The furniture style includes, for example, color, texture, material, or exotic element. However, users may still change the content of the attribute information according to actual needs.

In one embodiment, the processor 12 may recognize the attribute information based on the labeled design space and the attributes or types corresponding to objects in the space using algorithms of neural networks (e.g., YOLO (You only look once), region based convolutional neural networks (R-CNN), or Fast R-CNN) or feature-based matching algorithms (e.g., histogram of oriented gradient (HOG), scale-invariant feature transform (SIFT), Harr, or speeded up robust features (SURF)).

In one embodiment, to protect personal information, data analysis using tokenization may be employed to derive correlations between different furniture in the 3D space. For example, the correlation between individuals or their identifying information and furniture may be deleted.

The processor 12 provides the recommendation information of the 3D space according to the attribute information (step S230). Specifically, the recommendation information includes a style recommendation and/or a furniture recommendation. The style recommendation is, for example, a combination of space design and/or furniture suitable for the current space measurement or space type. The furniture recommendation is, for example, a furniture suitable for the current space type, furniture type, and/or furniture style. The recommendation information may be based on the similarity of the attribute information and/or the popularity of the corresponding style.

For example, the “living room” with the attribute information “3 rooms and 2 living rooms” has a “10-square-meter area with a 3-meter ceiling height,” a “sofa” that is “beige” and “plain-colored” with a “fabric” material, a “TV cabinet” that is “beige” and “wooden,” and a “60-inch” “television.” The living room layout with recommendation information as plain/beige includes sofa area (including various combinations of sofa areas that may be placed in the design), and TV cabinet area (including various combinations that may be placed in the TV cabinet area). The combinations may include furniture or style plans, such as a wooden TV cabinet.

For another example, the “living room” with the attribute information “3 rooms and 2 living rooms” has a “10-square-meter area with a 3-meter ceiling height,” a “sofa” that is “beige” and “plain-colored” with a “fabric” material, a “TV cabinet” that is “beige” and “wooden,” and a “60-inch” “television.” The recommendation information includes a sofa, a lamp, a TV cabinet, and a chair in a first style, as well as a sofa, a TV cabinet, and a chair in a second style, and so on.

It should be noted that the space measurement and space type in the attribute information may affect the size of the furniture in the recommendation information. For example, a smaller space excludes furniture that occupies a larger space. For another example, in the case of the space type of a living room, furniture suitable for a living room is recommended. Furthermore, the recommendation information may further include a recommended placement position for the furniture, and the placement position of the furniture may vary depending on space measurement or different space types.

In one embodiment, the processor 12 may predict the recommendation information through a predictive model. The predictive model is based on a machine learning algorithm and trained by inputting at least one or more labeled samples, and each labeled sample includes correspondence between attribute and style or correspondence between attribute and furniture. The machine learning algorithm includes, for example, support vector machine (SVM), deep learning, random forest, or decision tree. The machine learning algorithm may analyze the training samples to obtain patterns and make inferences on unknown data based on the patterns. For example, the predictive model establishes the correlation between nodes in hidden layers between attribute and style or between attribute and furniture according to the labeled samples. The predictive model is a machine learning model constructed through learning, and may be used to infer or make predictions based on the evaluation data (e.g., attribute information).

In one embodiment, the recommendation information includes multiple recommended options, such as the first style and the second style in the preceding example. The processor 12 may sort the recommended options according to similarity and/or popularity. The similarity refers to the similarity between the recommendation information and the attribute information. The popularity may be determined based on statistics from the Internet or merchants. A recommended option with higher similarity or popularity has a higher priority, for example, the recommended option in the user interface is ranked higher.

In an embodiment, the processor 12 may display the recommendation information through a display (not shown in the figure) or transmit the recommendation information through a communication transceiver (not shown in the figure).

In one embodiment, an online shopping or e-commerce program installed on the computing apparatus 10 may allow the recommended furniture to be added to the shopping cart for direct purchasing.

In one embodiment, the processor 12 may obtain purchase information. The purchase information includes one or more purchased furniture. For example, the processor 12 may connect to the online shopping or e-commerce program and obtain the purchase list related to furniture. The processor 12 may update the predictive model according to the purchase information. In other words, the model parameters of the predictive model may be updated or modified based on the purchase information, thereby changing or adjusting the recommendation information. In response to the fact that the training samples of the predictive model are limited, the predictive model tends to recommend recommendation information that in line with general standards. In addition, as the amount of personal sample (e.g., purchase information) increases, the recommendation information is more in line with personal preference.

To sum up, in the arrangement recommendation method of the 3D space and the computing apparatus in the embodiment of the disclosure, once the real space is scanned and modeled, all objects in the 3D space may be analyzed, labeled, and examined. Based on the comprehensive understanding and analysis of factors such as all objects in the space and spatial dimensions (i.e., attribute information), layout decisions may be generated and used to recommend relevant objects and/or arrangements. In this way, human effort and decision-making time may be reduced, thereby enhancing the user experience.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. An arrangement recommendation method of a three-dimensional (3D) space, comprising:
obtaining a 3D space, wherein the 3D space is established by scanning a space;
identifying attribute information of the 3D space, wherein the attribute information comprises at least one of appearance measurement, space type, furniture type, and furniture style; and
providing recommendation information of the 3D space according to the attribute information, wherein the recommendation information comprises at least one of a style recommendation and a furniture recommendation.

2. The arrangement recommendation method of the 3D space according to claim 1, wherein providing the recommendation information of the 3D space according to the attribute information comprises:
predicting the recommendation information through a predictive model, wherein the predictive model is based on a machine learning algorithm and trained by inputting at least one labeled sample, and each labeled sample comprises correspondence between attribute and style or correspondence between attribute and furniture.

3. The arrangement recommendation method of the 3D space according to claim 2, further comprising:
obtaining purchase information, wherein the purchase information comprises at least one purchased furniture; and
updating the predictive model according to the purchase information.

4. The arrangement recommendation method of the 3D space according to claim 1, wherein the recommendation information comprises a plurality of recommended options, and providing the recommendation information of the 3D space according to the attribute information comprises:
sorting the recommended options according to similarity or popularity.

5. A computing apparatus, comprising:
a memory, configured to store a code; and
a processor, coupled to the memory and loading the code to execute:
obtaining a 3D space, wherein the 3D space is established by scanning a space;
identifying attribute information of the 3D space, wherein the attribute information comprises at least one of appearance measurement, space type, furniture type, and furniture style; and
providing recommendation information of the 3D space according to the attribute information, wherein the recommendation information comprises at least one of a style recommendation and a furniture recommendation.

6. The computing apparatus according to claim 5, wherein the processor is further used for:
predicting the recommendation information through a predictive model, wherein the predictive model is based on a machine learning algorithm and trained by inputting at least one labeled sample, and each labeled sample comprises correspondence between attribute and style or correspondence between attribute and furniture.

7. The computing apparatus according to claim 6, wherein the processor is further used for:
obtaining purchase information, wherein the purchase information comprises at least one purchased furniture; and
updating the predictive model according to the purchase information.

8. The computing apparatus according to claim 5, wherein the recommendation information comprises a plurality of recommended options, and the processor is further used for:
sorting the recommended options according to similarity or popularity.
